(19) United States
(12) Patent Application Publication
(10) Pub. No.: US 2011/0279948 A1
(43) Pub. Date: Nov. 17, 2011

(54) Electronic Device

(76) Inventors: Hirofumi Morita, Tokyo (JP); Naoya Shigenobu, Tokyo (JP)

(21) Appl. No.: 13/045,378

(22) Filed: Mar. 10, 2011

(30) Foreign Application Priority Data
May 13, 2010 (JP) 2010-111024

(51) Int. Cl. H05K 5/02

(52) U.S. Cl. 361/679.01

(57) ABSTRACT

According to one embodiment, an electronic device includes a housing, a support member, and an antenna. The housing houses an electronic component. The support member is fixed to the housing. The antenna is fixed to the support member. The support member is arranged spaced apart from an outer surface of a main body of the electronic component.

### CROSS-REFERENCE TO RELATED APPLICATIONS

This application is based upon and claims the benefit of priority from Japanese Patent Application No. 2010-111024, filed May 13, 2010, the entire contents of which are incorporated herein by reference.

### FIELD

Embodiments described herein relate generally to an electronic device.

### BACKGROUND

There have been known electronic devices provided with an antenna that is attached to the back wall of the housing, in which a display panel is housed as being exposed on the front side (see, for example, Patent Application Publication (KOKAI) No. 2004-102898).

In this type of electronic devices, there is a case that the attachment of an antenna to the back wall of the housing makes it difficult to assemble or disassemble the housing.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of an electronic device in the open position according to an embodiment;

FIG. 2 is an exemplary perspective view of the electronic device in the closed position in the embodiment;

FIG. 3 is an exemplary exploded perspective view of a second body of the electronic device in the embodiment;

FIG. 4 is an exemplary plan view of an antenna unit of the electronic device in the embodiment;

FIG. 5 is an exemplary cross-sectional view of the second body of the electronic device taken along line V-V of FIG. 4 in the embodiment;

FIG. 6 is an exemplary cross-sectional view of the second body of the electronic device taken along line VI-VI of FIG. 4 in the embodiment;

FIG. 7 is an exemplary perspective view of an antenna bracket according to a modification of the embodiment;

FIG. 8 is an exemplary perspective view of an antenna bracket according to another modification of the embodiment; and

FIG. 9 is an exemplary perspective view of an antenna bracket according to still another modification of the embodiment.

### DETAILED DESCRIPTION

Various embodiments will be described hereinafter with reference to the accompanying drawings. In general, according to one embodiment, an electronic device comprises a housing, a support member, and an antenna. The housing is configured to house an electronic component. The support member is configured to be fixed to the housing. The antenna is configured to be fixed to the support member. The support member is configured to be arranged spaced apart from the outer surface of the main body of the electronic component.

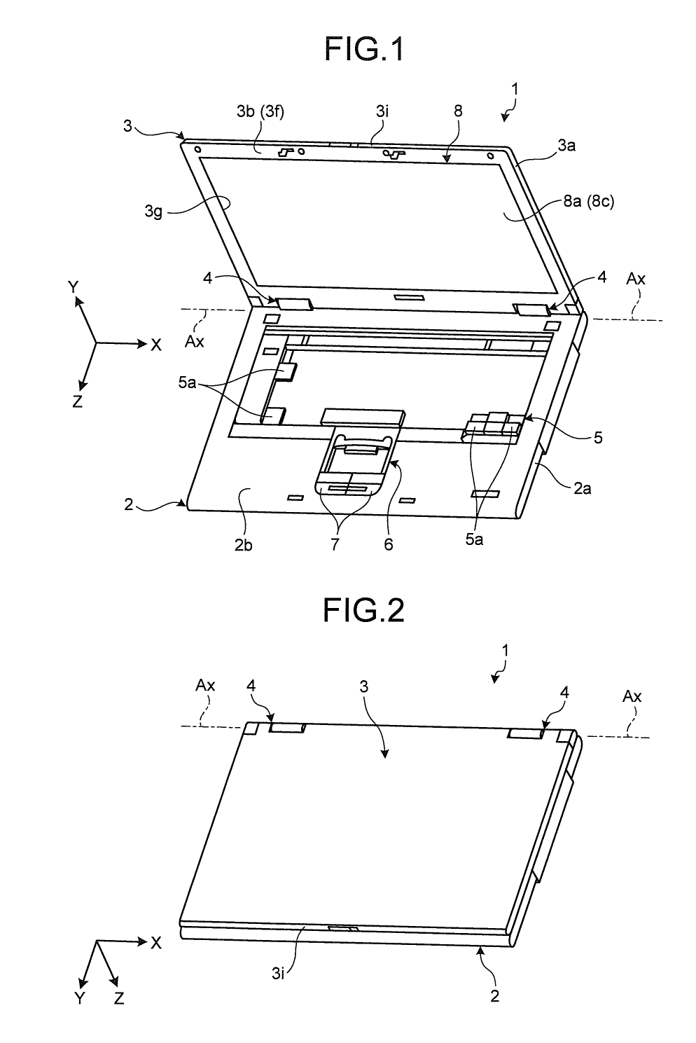

As illustrated in FIGS. 1 and 2, an electronic device 1 of an embodiment is, for example, a notebook personal computer. The electronic device 1 comprises a flat rectangular first body 2 and a flat rectangular second body 3. The first body 2 and the second body 3 are connected by a hinge mechanism 4 to be relatively rotatable about a rotation axis Ax between an open position as illustrated in FIG. 1 and a closed position as illustrated in FIG. 2. Hereinafter, for the sake of convenience of description, the width direction (horizontal direction) of the second body 3 will be referred to as “X direction”, the direction of an edge of the second body 3 will be referred to as “Y direction”, and the thickness direction of the second body 3 will be referred to as “Z direction”. The X, Y, and Z directions are perpendicular to one another.

The first body 2 is provided with a keyboard 5, a pointing device 6, a click button 7, and the like as input devices, which are exposed on a front surface 2b as the outer surface of a housing 2a. On the other hand, the second body 3 is provided with a display panel 8 as a display device (an electronic component), which is exposed on a front surface 3b as the outer surface of a housing 3a. The display panel 8 may be, for example, a liquid crystal display (LCD) panel. When the first body 2 and the second body 3 are in the open position, the keyboard 5, the pointing device 6, the click button 7, the display panel 8, and the like are exposed to allow the user to use them. On the other hand, in the closed position, the front surface 2b closely faces the front surface 3b, and the keyboard 5, the pointing device 6, the click button 7, the display panel 8, and the like are covered between the housings 2a and 3a. Incidentally, FIG. 1 does not illustrate all keys of the keyboard 5 but only keys 5a.

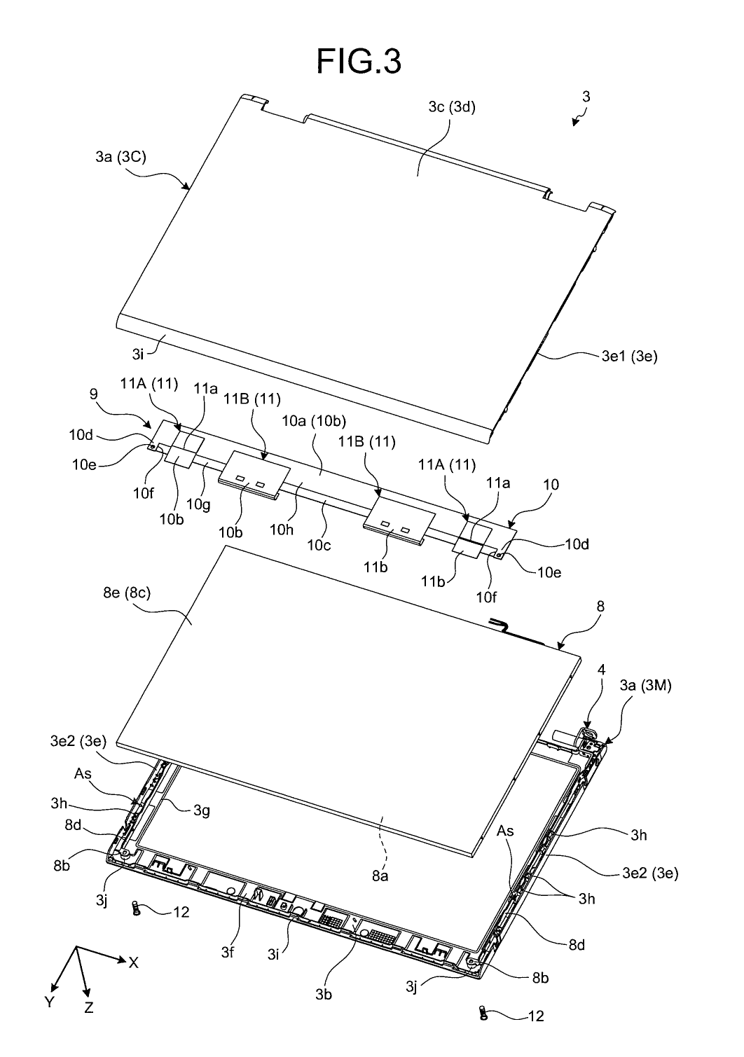

As illustrated in FIGS. 1 and 2, the second body 3 has a rectangle shape long in the X direction and short in the Y direction in a plan view from the Z direction, and is flat in the Z direction. As illustrated in FIG. 3, the housing 3a of the second body 3 comprises a bottom wall 3d, a first divisional body 3C, a top wall 3f, and a second divisional body 3M. The bottom wall 3d forms a back surface 3c. The first divisional body 3C comprises a side wall 3e1 that extends at the periphery of the bottom wall 3d. The top wall 3f forms the front surface 3b. The second divisional body 3M comprises a side wall 3e2 that extends at the periphery of the top wall 3f. A rectangular opening 3g is formed in the center of the top wall 3f of the second divisional body 3M. A display screen 8a of the display panel 8 is exposed form the opening 3g. The side walls 3e1 and 3e2 of the first divisional body 3C and the second divisional body 3M overlap one on top of the other and form a side wall (peripheral wall) 3e of the housing 3a. That is, the framework of the second body 3 is formed of the bottom wall 3d, the top wall 3f, the side wall 3e, and the like. The housing 3a is made of metal material, synthetic resin material, or the like.

As illustrated in FIG. 3, the second body 3 houses the display panel 8 and an antenna unit 9 inside the framework formed of the first divisional body 3C and the second divisional body 3M.

The display panel 8 is rectangular in a plan view from the Z direction, and is relatively thin and flat, i.e., the thickness (the height in the Z direction) is small. The display panel 8 is located at substantially the center of the housing 3a. The display panel 8 is attached to the first divisional body 3C by, for example, fixing brackets 8b provided at the four corners of the display panel 8 using fixing members such as screws 12 or the like. While FIG. 3 illustrates a main body 8c of the display panel 8 separately from the brackets 8b, the display panel 8 is attached to the first divisional body 3C as having the brackets 8b attached to the main body 8c in practice. An end of the brackets 8b is connected to the hinge mechanism 4.

As illustrated in FIG. 3, an elongated frame-like cable routing area As is formed between a strip-like flat component side surface 8d of the display panel 8 and the side wall 3e of the housing 3a, i.e., around the component side surface 8d of the display panel 8 (the main body 8c or the brackets 8b) in the housing 3a. One or more cables (not illustrated) are routed in the cable routing area As. A plurality of cables (for example, three cables) are routed in parallel depending on the position. Examples of the cables include an antenna cable connected to an antenna 11 and a camera cable connected to a camera (not illustrated).

As illustrated in FIG. 3, in the embodiment, protrusions 3h are provided on the top wall 3f of the second divisional body 3M to face the side wall 3e2 (3e) being spaced in parallel therefrom. The protrusions 3h are arranged in parallel with the component side surface 8d of the display panel 8 and the side wall 3e between the component side surface 8d and the side wall 3e. The protrusions 3h are located intermittently at a plurality of positions, respectively, along the component side surface 8d. A cable is routed between the side wall 3e and the protrusions 3h arranged in an array. That is, in the embodiment, the array of the protrusions 3h and the side wall 3e define the cable routing area As. The protrusions 3h face the component side surface 8d of the display panel 8. When the display panel 8 relatively moves in the in-plane direction along the display screen 8a in the housing 3a due to, for example, the action of an inertial force and comes in contact with the protrusions 3h, the protrusions 3h are tilted and deformed by the contact, thereby absorbing the shock energy. That is, in the embodiment, the protrusions 3h function as a shock or energy absorber to increasingly protect the display panel 8.

An antenna unit 9 comprises an antenna support member 10 and a plurality of antennas 11A and 11B (11). The antenna 11 is formed by providing a device, an electronic component, a conductor path, and the like (all not illustrated) on a relatively small and thin circuit board or a film. For example, the antenna 11 may be formed as a third generation (3G) antenna according to the international mobile telecommunications (IMT) 2000 standard or a wireless local area network (LAN) antenna. The antenna 11A is configured to be tiltable when bent at a bend line 11a. The antenna 11 is connected to a communication circuit mounted on a circuit board (not illustrated) housed in the first body 2 via a cable (not illustrated) routed in the cable routing area As. The end (the tip in the Y direction) of the antenna 11 is mainly in charge of the communication function.

In the embodiment, the antenna support member 10 is formed in a strip-like plate having a substantially constant width and extending along an edge 3i of the end (the tip in the Y direction) of the housing 3a of the second body 3. In the antenna support member 10, at least a portion where the antenna 11 is attached (for example, all over a back surface 10a) is conductive. The conductive portion functions as the ground of the antenna 11. Accordingly, the antenna support member 10 can be formed as, for example, a strip-like metal conductor or a strip-like insulator (for example, synthetic resin, etc.) provided with a conductive layer (for example, conductive foil, a conductive film, a conductive plate, etc.) on the back surface 10a. The conductive portion of the antenna support member 10 is electrically connected to the ground of the second body 3 and also a ground electrode (not illustrated) of the antennas 11. This results in an equal ground potential between the second body 3 and the antennas 11, thereby reducing the communication trouble such as noise contamination.

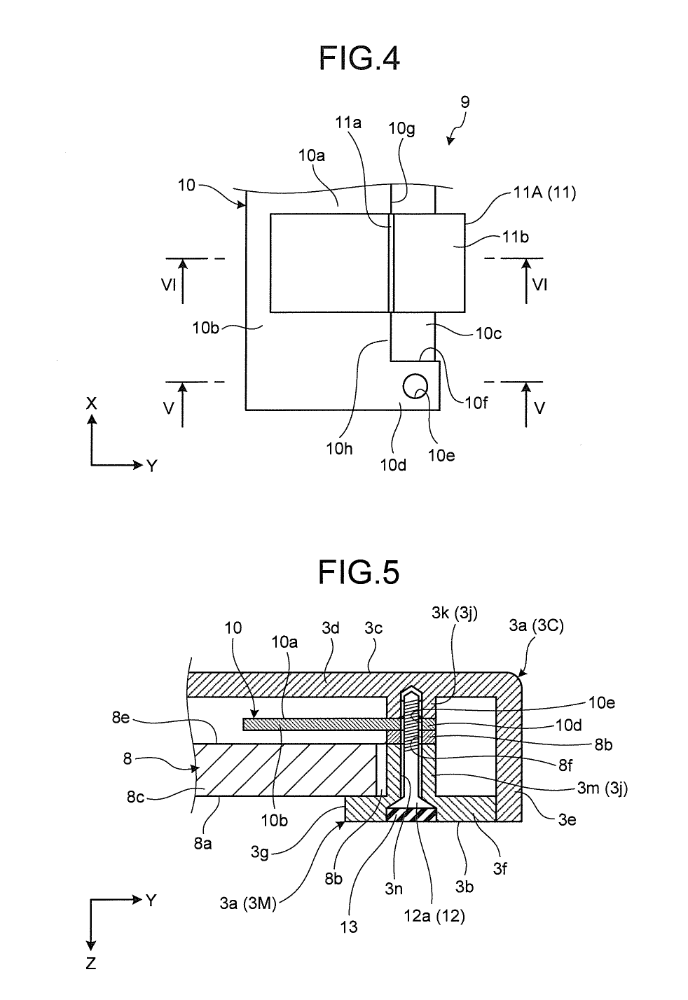

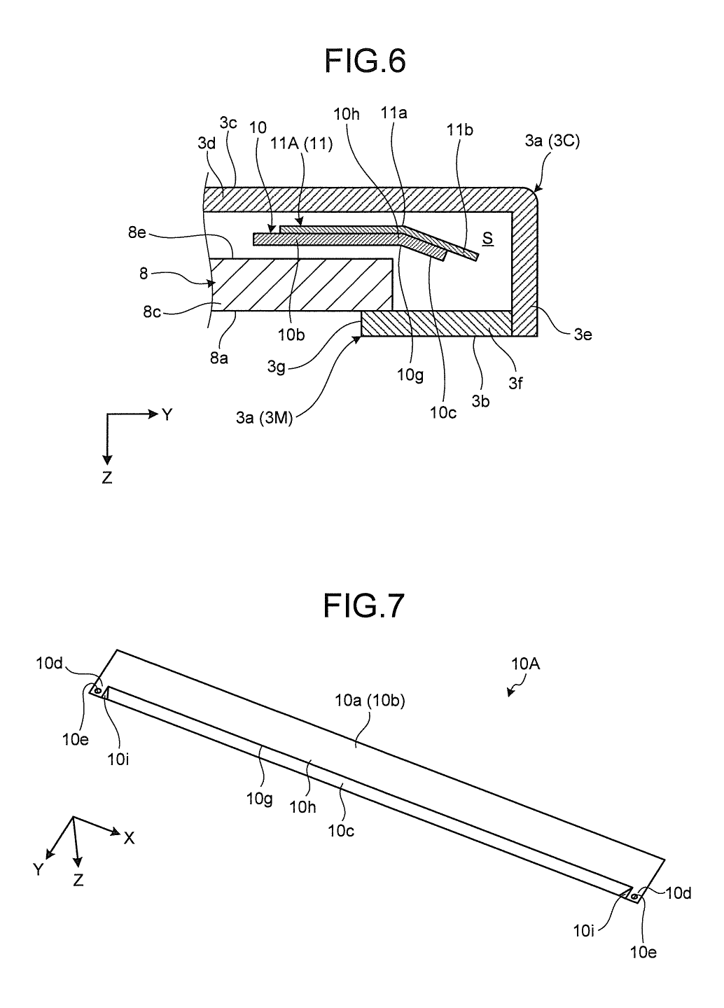

As illustrated in FIGS. 4 to 6, the antenna support member 10 comprises a strip-like base 10b, a strip-like inclined portion 10c, and a bracket 10d. The base 10b is located between the bottom wall 3d of the housing 3a and a back surface 8e as the outer surface of the display panel 8. The inclined portion 10c is located at the end (the tip in the Y direction) of the base 10b. The bracket 10d is fixed to a fixing portion 3j of the housing 3a. As illustrated in FIG. 6, in the embodiment, the antenna support member 10 has a cross-section in a bent shape with the base 10b and the inclined portion 10c. Compared to the straight shape without a bent, the antenna support member 10 has a high rigidity. The bracket 10d is provided as a rectangular area on both sides of the base 10b in the longitudinal direction (both sides in the width direction of the second body 3, i.e., both sides in the X direction) and the end (the tip in the Y direction). The bracket 10d is provided with a through hole 10e as a through portion through which the attachment screw 12 passes.

As illustrated in FIG. 6, the base 10b is arranged in parallel with the bottom wall 3d and the back surface 8e of the display panel 8, spaced apart from both the bottom wall 3d and the display panel 8. With this, the antenna 11 attached to the antenna support member 10 is also spaced apart from both the bottom wall 3d and the display panel 8. Since the antenna 11 is not located near the bottom wall 3d or the display panel 8, the communication characteristic of the antenna 11 is not affected. If the antenna support member 10 comes in contact with the back surface 8e of the display panel 8, the display panel 8 is pushed by the antenna support member 10 upon assembly of the second body 3 or the like, and may be adversely affected. From this viewpoint, in the embodiment, both the base 10b and the inclined portion 10c of the antenna support member 10 are separate from the display panel 8. Thus, the display panel 8 can be prevented from being pushed by the antenna support member 10.

As illustrated in FIGS. 3 and 4, the inclined portion 10c is separated from the base 10b (the bracket 10d) side by a pair of notches 10f formed on both sides of the antenna support member 10 in the longitudinal direction. As illustrated in FIG. 6, the inclined portion 10c is formed by bending the antenna support member 10 forward (the tip side in the Z direction) at a bend line 10g that connects the ends of the notches 10f on the depth side. That is, as illustrated in FIG. 6, the inclined portion 10c extends forward from an edge 10h of the base 10b toward the end side (the tip side in the Y direction). Accordingly, as illustrated in FIG. 6, the antenna 11A is bent along the bent of the antenna support member 10, and an end 11b of the antenna 11A is located near the center of a space S surrounded by the side wall 3e, the top wall 3f, and the bottom wall 3d as the framework of the housing 3a on the end side of the second body 3. With this, the end 11b of the antenna 11 is located near the framework of the housing 3a, which prevents the communication characteristic of the antenna 11 from being affected. The specifications (size, angle, etc.) of the inclined portion 10c are set to achieve appropriate characteristics of the antenna 11.

As illustrated in FIG. 5, the bracket 10d is held between a boss 3k as the fixing portion 3j provided to the first divisional body 3C and a boss 3m as the fixing portion 3j provided to the second divisional body 3M together with the brackets 8b of the display panel 8. The bracket 10d is attached to the housing 3a with the screw 12. In the embodiment, a female screw portion is provided to the boss 3k of the first divisional body 3C. By screwing the screws 12 passing through a through hole 3n formed in the second divisional body 3M and the through holes 8f and 10e formed in the brackets 8b and 10d from the second divisional body 3M side, the first divisional body 3C, the second divisional body 3M, the display panel 8, and the antenna unit 9 are combined. A head 12a of the screw 12 is covered with a plug 13 pushed into the opening end of the through hole 3n.

The antenna 11 is attached to the antenna support member 10 by adhesive, adhesive tape, or the like. As described above, the ground electrode (not illustrated) of the antenna 11 is electrically connected to the conductive portion of the antenna support member 10. Accordingly, conductive adhesive, adhesive tape, or the like is preferably used to attach the antenna 11 to the antenna support member 10. The antenna 11 may be attached to the antenna support member 10 attached to the housing 3a, or the antenna unit 9 where the antenna 11 is attached to the antenna support member 10 may be attached to the housing 3a.

As described above, according to the embodiment, the electronic device 1 comprises the housing 3a that houses the display panel 8 as an electronic component, the antenna support member 10 fixed to the housing 3a, and the antenna 11 fixed to the antenna support member 10. Accordingly, compared to the case where the antenna 11 is directly fixed to the housing 3a, the antenna 11 can be easily attached and detached. Besides, the plurality of antennas 11 can be attached to the one antenna support member 10, which further facilitates the attachment and detachment of the antenna 11.

According to the embodiment, the antenna support member 10 is arranged spaced apart from the back surface 8e as the outer surface of the display panel 8. Since the antenna 11 is not located near the display panel 8, the communication characteristic of the antenna 11 is not affected.

According to the embodiment, the antenna support member 10 is arranged along the framework of the housing 3a (the bottom wall 3d, the side wall 3e, the top wall 3f, etc.) and fixed to the framework. Thus, the antenna support member 10 reinforces the framework, thereby increasing the rigidity of the housing 3a.

According to the embodiment, the antenna support member 10 is arranged across between both sides of the one side wall 3e as the framework in the longitudinal direction. Thus, the antenna support member 10 reinforces the entire side wall 3e, thereby further increasing the rigidity of the housing 3a.

According to the embodiment, the antenna support member 10 has a cross-section in a bent shape. This increases the rigidity of the antenna support member 10, and further increases the rigidity of the housing 3a.

According to the embodiment, the housing 3a comprises the top wall 3f and the bottom wall 3d facing each other with a space therebetween, and the side wall 3e that connects between the top wall 3f and the bottom wall 3d. The antenna support member 10 comprises the base 10b and the inclined portion 10c. The base 10b is located near one of the top wall 3f and the bottom wall 3d (the bottom wall 3d). The inclined portion 10c is connected to the base 10b and extends in the direction distant from the bottom wall 3d as coming closer to the side wall 3e. Thus, the antenna 11 can be located along the inclined portion 10c near the center of the space surrounded by the bottom wall 3d, the side wall 3e, the top wall 3f. This prevents the communication characteristic of the antenna 11 from being affected by the bottom wall 3d, the side wall 3e, the top wall 3f.

According to the embodiment, the housing 3a comprises the plurality of divisional bodies 3C and 3M. The antenna support member 10 is fixed to the housing 3a with the screws 12 as fixing members for fixing the divisional bodies 3C and 3M. Therefore, compared to the case where a screw for connecting the divisional bodies 3C and 3M to each other and a screw for connecting the antenna support member 10 to the housing 3a are separately provided, less components are required, and also assembly process can be reduced.

According to the embodiment, an electronic component is the display panel 8 as a display device. The housing 3a comprises the first divisional body 3C that covers the back side of the display panel 8 and the second divisional body 3M that covers the front side of the display panel 8 with the display screen 8a thereof being exposed. The harness (not illustrated) of the antenna 11 is fixed to the second divisional body 3M. Accordingly, the first divisional body 3C that covers the back side of the display panel 8 can be relatively easily attached and detached. This facilitate the removal of the first divisional body 3C from the housing 3a when, for example, the first divisional body 3C is removed from the assembled electronic device 1 to print a pattern, letters or characters, an image, or the like, or to attach a seal, a film, or the like (to embellish) onto the back surface 3c. Moreover, it is possible to avoid trouble in the process or the operation caused by the antenna 11 or the harness attaching to the first divisional body 3C upon setting the first divisional body 3C on a printer or the like for printing.

According to the embodiment, upon assembling the electronic device 1, the operator can attach the plurality of antennas 11 to the antenna support member 10 as the integrated antenna unit 9. Thus, the antennas 11 can be attached or detached at a time, which reduces the attachment/detachment work.

According to a modification of the embodiment illustrated in FIG. 7, an antenna support member 10A comprises bend portions 10i that connect the brackets 10d as both ends in the longitudinal direction (i.e., the X direction) and the inclined portion 10c in the longitudinal direction of the antenna support member 10A. With this, the rigidity of the antenna support member 10A can be further increased, and the reinforcement of the housing 3a by the antenna support member 10A can be improved.

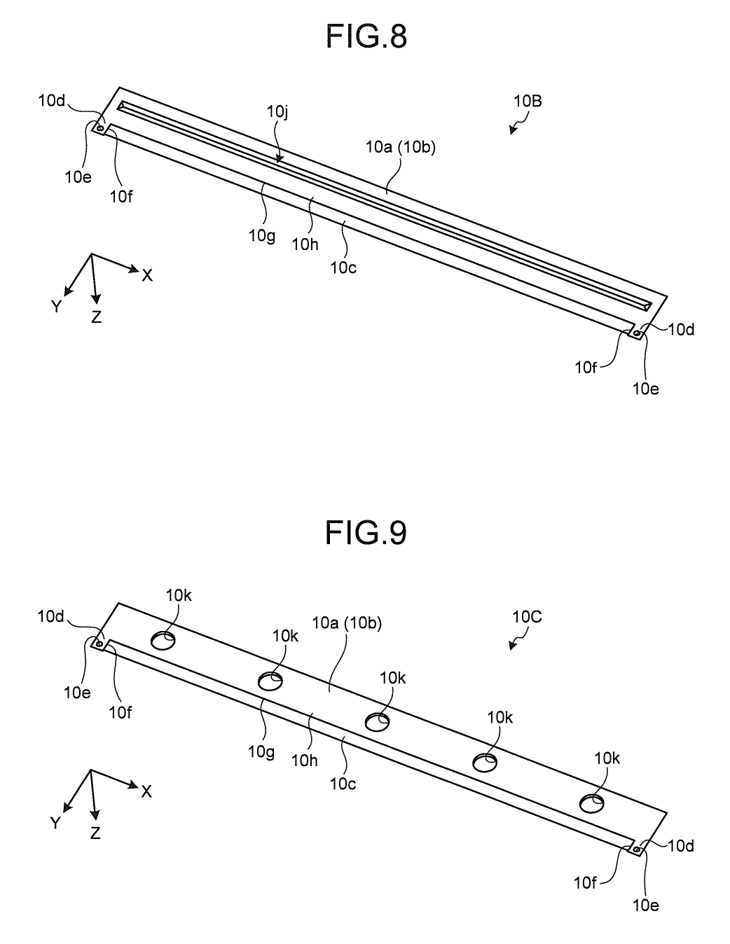

According to a modification of the embodiment illustrated in FIG. 8, an antenna support member 10B comprises a protruding portion 10j extending along the longitudinal direction. The protruding portion 10j may be formed by, for example, hollowing forward the center of the base 10b in the width direction in a constant width. The protruding portion 10j further increase the rigidity of the antenna support member 10B, and the reinforcement of the housing 3a by the antenna support member 10B can be further improved. The protruding portion may be protruded backward in a range in which no trouble arises in the performance of the antenna 11. The protruding portion may be formed partly, intermittently, or in a stepped shape.

According to a modification of the embodiment illustrated in FIG. 9, an antenna support member 10C comprises a through hole 10k as a through portion passing through the top to the bottom (in the front-back direction). This reduces the weight of the antenna support member 10C. The through portion may be formed as a notch, and may be provided to the inclined portion 10c. Besides, the through portion may be used to avoid interference with another component.

The foregoing embodiment is susceptible to considerable variation in the practice. For example, while the embodiment is described above as being applied to a notebook personal computer, the embodiment may be applied to other electronic devices. The specifications (structure, form, size, weight, number, material, arrangement, location, etc.) can be changed as required for the housing, the support member, the antenna, the framework, the cross-section, the protruding portion, the base, the inclined portion, the fixing member, the display device, the first divisional body, the second divisional body, and the like.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic device comprising:
a housing configured to house an electronic component;
a support member configured to be fixed to the housing; and
an antenna configured to be fixed to the support member, wherein
the support member is configured to be arranged spaced apart from an outer surface of a main body of the electronic component.

2. The electronic device of claim 1, wherein a plurality of antennas are fixed to the support member.

3. The electronic device of claim 1, wherein the support member is configured to be arranged along a framework of the housing, and fixed to the framework.

4. The electronic device of claim 3, wherein the support member is configured to be arranged across between both sides of a side wall as the framework in a longitudinal direction.

5. The electronic device of claim 3, wherein the support member comprises a cross-section in a bent shape.

6. The electronic device of claim 3, wherein the support member comprises a protruding portion configured to extend along a longitudinal direction of the support member.

7. The electronic device of claim 1, wherein
the housing comprises a top wall and a bottom wall facing each other with a space therebetween, and a side wall configured to connect the top wall and the bottom wall, and
the support member comprises
a base located near one of the top wall and the bottom wall, and
an inclined portion connected to the base, the inclined portion configured to extend in a direction distant from the one of the top wall and the bottom wall as coming closer to the side wall.

8. The electronic device of claim 7, wherein the support member comprises bend portions configured to connect both ends of the support member in a longitudinal direction and the inclined portion in the longitudinal direction of the support member.

9. The electronic device of claim 1, wherein
the housing comprises a plurality of divisional bodies, and
the support member is configured to be fixed to the housing with a fixing member for fixing the divisional bodies.

10. The electronic device of claim 1, wherein
the electronic component is a display device,
the housing comprises a first divisional body configured to cover a back side of the display device and a second divisional body configured to cover a front side of the display device with a display screen of the display device being exposed, and
a harness of the antenna is configured to be fixed to the second divisional body.
